(19) United States
(12) Patent Application Publication
(10) Pub. No.: US 2023/0199966 A1
(43) Pub. Date: Jun. 22, 2023

(54) CIRCUIT BOARD WITH EMBEDDED COMPONENT AND METHOD OF FABRICATING THE SAME

(71) Applicants: Avary Holding (Shenzhen) Co., Ltd., Shenzhen (CN); HongQiSheng Precision Electronics (QinHuangdao) Co., Ltd., Hebei Province (CN); Garuda Technology Co., Ltd., New Taipei City (TW)

(72) Inventors: Zi-Qiang GAO, Shenzhen (CN); Xian-Qin HU, Shenzhen (CN)

(21) Appl. No.: 17/679,554

(22) Filed: Feb. 24, 2022

(30) Foreign Application Priority Data
Dec. 22, 2021 (CN) 202111577601.5

(51) Int. Cl. H05K 1/18; H05K 3/46

(52) U.S. Cl. CPC H05K 1/185; H05K 3/4644; H05K 2201/0154

(57) ABSTRACT

A circuit board with embedded components and a method of fabricating the same are provided. The method includes coating an adhesive layer over a substrate, and disposing electronic components on the adhesive layer. Subsequently, after disposing a dielectric layer over the electronic components and the adhesive layer, the substrate and the adhesive layer are removed to form an embedded layer. Then, a wiring layer is formed on the electronic components, and conductive connecting components are formed within the dielectric layer. A cover layer is laminated over the dielectric layer and the wiring layer. Therefore, the electronic components are embedded within the dielectric layer, and the wiring layer electrically connecting to the electronic components are precisely located on a surface of the embedded layer.

### RELATED APPLICATION

This application claims priority to China Application Serial Number 202111577601.5 filed Dec. 22, 2021, which is herein incorporated by reference in its entirety.

### BACKGROUND

### Field of Invention

The disclosure relates to a circuit board with embedded components and a method of fabricating the same.

### Description of Related Art

In recent years, due to the progression of electronic devices, the properties of multifunctionality, high circuit density, and miniaturization are the main directions of research. Therefore, in order to achieve those requirements, higher circuit density should be designed on a substrate with limited area, and more electronic components, such as passive components and active components, should be disposed on the substrate. To achieve the above purpose, embedded component technology by embedding the electronic components into a dielectric layer of the substrate becomes a technical means to fulfil the above requirement.

### SUMMARY

An aspect of the invention is to provide a circuit board with embedded components, which comprises electronic components embedded within the dielectric layer.

Another aspect of the invention is to provide a method of fabricating a circuit board with embedded components.

According to the aforementioned aspect of the invention, a method of fabricating a circuit board with embedded components is provided, in which the method comprises providing a substrate first, and then coating an adhesive layer over a top surface of the substrate. Subsequently, a number of electronic components are disposed on the adhesive layer. Each of the electronic components has a functional surface and a number of pads exposed at the functional surfaces, and the adhesive layer covers the functional surfaces. Then, a dielectric layer is disposed over the electronic components and the adhesive layer. After disposing the dielectric layer, the substrate and the adhesive layer are removed to form an embedded layer with the exposed functional surfaces. After forming the embedded layer, a wiring layer is formed on the functional surfaces. The wiring layer is electrically connected to the electronic components. A number of conductive connecting components are formed within the dielectric layer. The embedded layer has a bottom surface on an opposite side of the functional surface. The conductive connecting components connect to the wiring layer, and an end of each of the conductive connecting components is exposed to the bottom surface of the embedded layer. After forming the conductive connecting components, a cover layer is laminated over the dielectric layer and the wiring layer.

Another aspect of the disclosure provides a circuit board with embedded components, which comprises a dielectric layer, a number of electronic components embedded within the dielectric layer, a wiring layer disposed on a top surface of the dielectric layer, a number of conductive connecting components penetrated the dielectric layer and a cover layer. Each of the electronic components has a functional surface and a number of pads exposed at the functional surfaces. The wiring layer is electrically connected to the electronic components. The conductive connecting components are disposed between the electronic components and electrically connecting to the wiring layer. An end of each of the conductive connecting components is exposed to a bottom surface of the dielectric layer. The cover layer is disposed over the dielectric layer, the wiring layer and the conductive connecting components.

Therefore, with the application of the circuit board with embedded components and the method of fabricating the same of the invention, after the electronic components are embedded within the dielectric layer, and the wiring layer is formed on the dielectric layer, such that the wiring layer is electrically connecting to the electronic components, and the wiring layer can be precisely located on a surface of the embedded layer.

It is to be understood that both the foregoing general description and the following detailed description are by examples, and are intended to provide further explanation of the invention as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-section diagram of a portion of a device after providing a substrate and an adhesive layer of a method of fabricating a circuit board with embedded components according to some embodiments of the present invention.

FIG. 2 illustrates a cross-section diagram of a portion of a device after disposing electronic components of a method of fabricating a circuit board with embedded components according to some embodiments of the present invention.

FIG. 3 illustrates a cross-section diagram of a portion of a device after disposing a baseplate of a method of fabricating a circuit board with embedded components according to some embodiments of the present invention.

FIG. 4 illustrates a cross-section diagram of a portion of a device after disposing a dielectric layer of a method of fabricating a circuit board with embedded components according to some embodiments of the present invention.

FIG. 5 illustrates a cross-section diagram of a portion of a device after forming via holes of a method of fabricating a circuit board with embedded components according to some embodiments of the present invention.

FIG. 6 illustrates a cross-section diagram of a portion of a device after removing the substrate and the adhesive layer of a method of fabricating a circuit board with embedded components according to some embodiments of the present invention.

FIG. 7 illustrates a cross-section diagram of a portion of a device after forming a wiring layer of a method of fabricating a circuit board with embedded components according to some embodiments of the present invention.

FIG. 8 illustrates a cross-section diagram of a portion of a circuit board with embedded components according to some embodiments of the present invention.

FIG. 9 illustrates a cross-section diagram of a portion of a device after disposing electronic components and conductive pillars of a method of fabricating a circuit board with embedded components according to other embodiments of the present invention.

FIG. 10 illustrates a cross-section diagram of a portion of a device after disposing a dielectric layer of a method of fabricating a circuit board with embedded components according to other embodiments of the present invention.

FIG. 11 illustrates a cross-section diagram of a portion of a device after removing the substrate and the adhesive layer of a method of fabricating a circuit board with embedded components according to other embodiments of the present invention.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to the above, the present invention provides a circuit board with embedded components and a method of fabricating the same, which includes forming a wiring layer on a dielectric layer after embedding electronic components into the dielectric layer. Moreover, the wiring layer is electrically connected to the electronic components, and the wiring layer may be precisely located on a surface of the embedded layer.

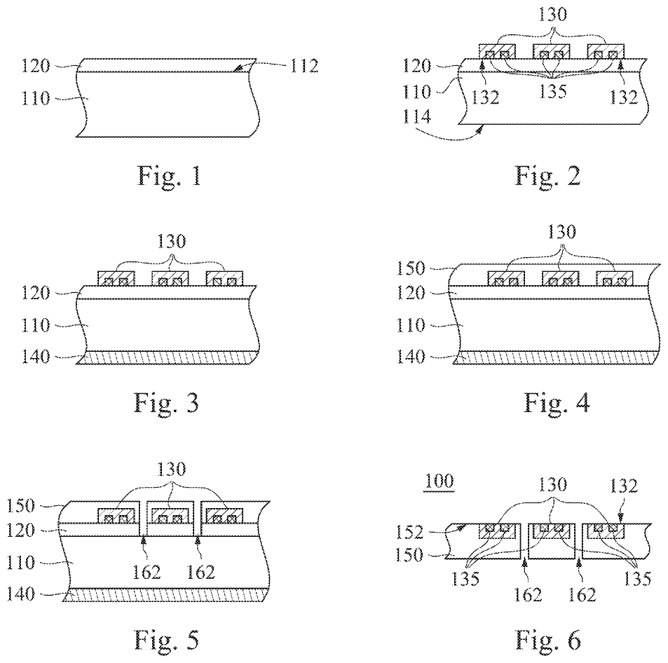

FIG. 1 to FIG. 8 are used to describe steps of some embodiments of the method of fabricating the circuit board with embedded components. First, referring to FIG. 1, a substrate 110 is provided, and an adhesive layer 120 is coated on a top surface 112 of the substrate 110. In some embodiments, the substrate 110 may be a transparent substrate or a non-transparent substrate to visible light, and the adhesive layer 120 may be an ultraviolet (UV) glue layer. If the adhesive layer 120 is the ultraviolet glue layer, a material of the substrate 110 has to be chosen to be penetrated by ultraviolet more easily, such as polyethylene terephthalate (PET), in which the substrate 110 may be non-transparent to visible light, but transparent to ultraviolet.

FIG. 2 illustrates a cross-section diagram after the operation of disposing electronic components 130 according to some embodiments of the present invention. In some embodiments, at least one electronic component 130 is disposed on the adhesive layer 120. Taking FIG. 2 as an example, a number of electronic components 130 are disposed on the adhesive layer 120. In some embodiments, these electronic components 130 comprise active components (such as transistors, integrated circuits, etc.), passive components (such as resistors, capacitors, inductors, etc.) or combination of the above components. Each electronic component 130 includes a functional surface 132 and a number of pads 135 exposed at the functional surfaces 132. The pads 135 are used for electronic components 130 electrically connecting to wires. In some embodiments, the adhesive layer 120 covers the functional surfaces 132, as shown in FIG. 2.

In the above embodiments, if the adhesive layer 120 is ultraviolet glue layer, after disposing the electronic components 130 on the adhesive layer 120, ultraviolet radiation is irradiated from a bottom surface 114 of the substrate 110 to solidify the ultraviolet glue layer and fix the electronic components 130. The bottom surface 114 of the substrate 110 is on an opposite side of the top surface 112 of the substrate 110.

FIG. 3 illustrates a cross-section diagram after the operation of disposing a baseplate 140 according to some embodiments of the present invention. The baseplate 140 may be selectively disposed on the bottom surface 114 of the substrate 110 after disposing electronic components 130 on the adhesive layer 120. In other words, the substrate 110 loaded with the electronic components 130 is disposed on the baseplate 140. The substrate 110 may be laid flat on the baseplate 140 in order to improve surface flatness of the substrate 110, which is beneficial to perform following operation of disposing a dielectric layer 150.

FIG. 4 illustrates a cross-section diagram after the operation of disposing a dielectric layer 150 according to some embodiments of the present invention. As shown in FIG. 4, the dielectric layer 150 is disposed over the electronic components 130 and the adhesive layer 120 such that the electronic components 130 are embedded within the dielectric layer 150. In some embodiments, the dielectric layer 150 comprises a resin material, and the resin material is chosen from a group consisting of polyimide (PI), modified polyimide (MPI), perfluoroalkoxy resin (PFA) and liquid crystal polymer (LCP).

In other embodiments, the dielectric layer 150 further comprises a number of hollow glass microspheres, which are incorporated into the resin material, such that the hollow glass microspheres are distributed within the resin material. Thus, the amount of usage of the resin material may be decreased, and shrinkage and warpage of the produced circuit board with the embedded components may be decreased. In addition, the dielectric constant of the hollow glass microspheres is 1.2 to 2.2; hence, the dielectric property of the dielectric layer 150 can be improved and beneficial for transmitting high-frequency signals. In some examples, maximum compression strength of the hollow glass microspheres is 30000 psi, thus increasing rigidity of the dielectric layer 150, in which an average particle size of the hollow glass microspheres is 5 μm to 100 μm.

Referring to FIG. 5, which illustrates a cross-section diagram after operation of forming via holes 162 according to some embodiments of the present invention. The via holes 162 are used to fabricate following conductive connecting components. In some embodiments, the via holes 162 are formed by using laser or plasma.

FIG. 6 illustrates a cross-section diagram after the operation of removing the substrate 110 and the adhesive layer 120 (and the baseplate 140, selectively) according to some embodiments of the present invention. In some embodiments, the operation of FIG. 6 is performed after the operation of FIG. 5. In the operation of FIG. 6, the substrate 110 in FIG. 5 may be flipped, and then the substrate 110, the adhesive layer 120 and the baseplate 140 are removed to form an embedded layer 100 including the electronic components 130 and the dielectric layer 150. Moreover, the functional surface 132 of the electronic components 130 are exposed, in which the functional surface 132 of the electronic components 130 are level with an upper surface 152 of the embedded layer 100. In addition, the above step of flipping may be omitted.

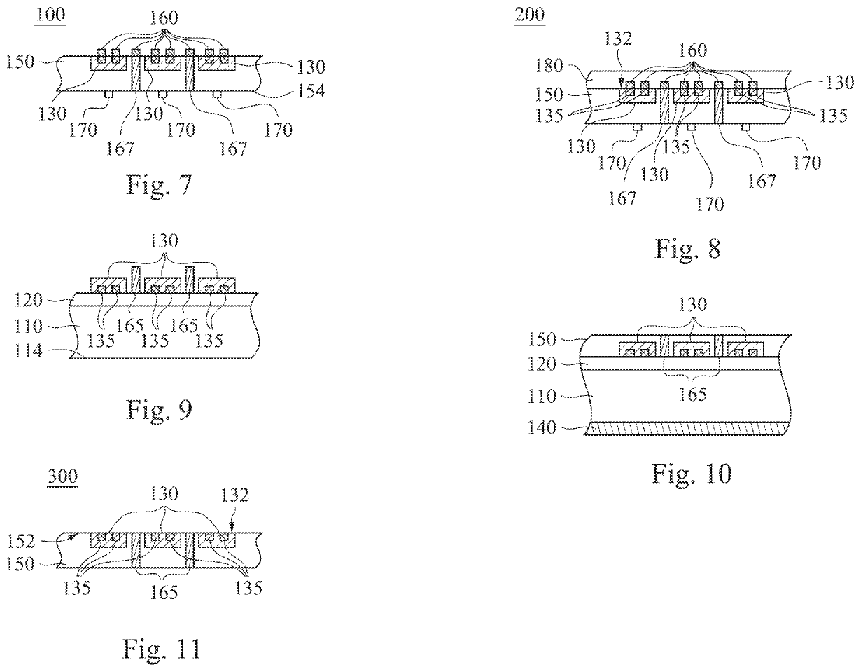

Then, as shown in FIG. 7, which illustrates a cross-section diagram after operation of forming a wiring layer 160 according to some embodiments of the present invention. The wiring layer 160 is formed on the functional surface 132 of the electronic components 130 to electrically connect to the pads 135 of the electronic components 130. Since after the operation of removing the substrate 110 and the adhesive layer 120, the pads 135 of the electronic components 130 are exposed to the surface of the dielectric layer 150; therefore, the wiring layer 160 may be precisely located on the surface of the dielectric layer 150. In some embodiments, the wiring layer 160 is formed by using sputtering and inkjet printing. For example, the inkjet printing comprises first printing conductive material over the embedded layer 100. Next, sintering is performed to solidify the conductive material, and then the wiring layer 160 is formed on the functional surface 132. The wiring layer 160 produced in the present invention may be fine wire, and depth precision may be controlled under 1 μm. In some embodiments, the wiring layer 160 (or the above conductive material) may comprise metal including copper, silver, nickel, chromium, titanium and/or alloy including the above metal.

The operation of forming wiring layer 160 comprises filling conductive material into the via holes 162 to form conductive connecting components 167, which can be formed simultaneously with the wiring layer 160. In some embodiments, a method for filling the conductive material into the via holes 162 includes electroplating, chemical plating, sputtering, copper fill plating, etc. In some embodiments, the conductive material may comprise metal including copper, silver, nickel, chromium, titanium and/or alloy including the above metal. The conductive connecting components 167 are connecting to the wiring layer 160. Moreover, ends of the conductive connecting components 167 are exposed to a bottom surface 154 of the embedded layer 100, while the bottom surface 154 is on an opposite side of the functional surface 132. In some embodiments, electrical pads 170 for electrically connecting to an external circuit board, such as printed circuit board or flexible circuit board, may also be formed on the bottom surface 154 of the embedded layer 100.

Referring to FIG. 8, which illustrates a cross-section diagram of a circuit board 200 with embedded components according to some embodiments of the present invention. A cover layer 180 is laminated over the embedded layer 100 shown in FIG. 7. To this end, the circuit board 200 with embedded components is basically fabricated. The cover layer 180, which functions as a protective film, covers the dielectric layer 150 and the wiring layer 160 of the embedded layer 100 for protecting the components (such as the electrical components 130, the wiring layer 160, and the conductive connecting components 167) from external pollution and oxidation.

In other embodiments, conductive pillars 165 as the conductive connecting components are disposed selectively while disposing the electrical components 130 and the following discussion is referring to FIG. 9 and FIG. 11. Referring to FIG. 9, which illustrates a cross-section diagram after operation of disposing electronic components 130 on the adhesive layer 120 shown in FIG. 1 according to other embodiments of the present invention. As shown in FIG. 9, the electrical components 130 and the conductive pillars 165 on the adhesive layer 120, in which the conductive pillars 165 are formed as subsequent conductive connecting components, such as the conductive connecting components 167 in the above embodiments. An advantage of embodiments shown in FIG. 9 to FIG. 11 is to decrease frequency of drilling or omit drilling process, thus helping simplify the process. In some embodiments, the conductive pillars 165 may comprise metal including copper, silver, nickel, chromium, titanium and/or alloy including the above metal.

After disposing the electrical components 130 and the conductive pillars 165 on the adhesive layer, the baseplate 140 is selectively disposed on the bottom surface 114 of the substrate 110. Then, as shown in FIG. 10, the dielectric layer 150 is disposed over the electrical components 130, the conductive pillars 165 and the adhesive layer 120. Afterwards, referring to FIG. 11, the substrate 110, the adhesive layer 120 and the baseplate 140 are removed to form an embedded layer 300 including the electrical components 130, the conductive pillars 165 and the dielectric layer 150. The functional surfaces 132 of the electrical components 130 are level with the upper surface 152 of the embedded layer 100.

Further, the steps disclosed by FIG. 7 and FIG. 8 are performed sequentially to form the wiring layer 160 on the functional surface 132 of the electrical components 130. In some embodiments, the electrical pads 170 (not shown) for electrically connecting to the external circuit board, such as printed circuit board or flexible circuit board, may be formed on the bottom surface of the embedded layer 300 simultaneously. Then, the cover layer 180 is laminated such that fabrication of the circuit board with the embedded components is basically completed. It is understood that although the substrate 110 is disposed on the baseplate 140 as shown in FIG. 4, FIG. 5 and FIG. 10, the present invention is not limited to disposing the baseplate 140.

With the application of the circuit board with embedded components and the method of fabricating the same in the present invention, the electrical components and the conductive connecting components are embedded within the dielectric layer, and then the substrate is removed to obtain the embedded layer. Since the pads of the electrical components are exposed to the surface of the embedded layer, the wiring layer electrically connected to the electrical components may be precisely located on the surface of the dielectric layer (or the embedded layer).

It is understood that the aforementioned steps described in the embodiments of the disclosure can be combined or skipped, and the order thereof can be adjusted according to actual requirements.

Although the disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the disclosure without departing from the scope or spirit of the invention. In view of the foregoing, it is intended that the disclosure cover modifications and variations of this invention provided they fall within the scope of the following claims.

What is claimed is:

1. A method of fabricating a circuit board with embedded components, comprising:
providing a substrate;
coating an adhesive layer over a top surface of the substrate;
disposing a plurality of electronic components on the adhesive layer, wherein each of the electronic components has a functional surface and a plurality of pads exposed at the functional surfaces, and the adhesive layer covers the functional surface;
disposing a dielectric layer over the electronic components and the adhesive layer;
after disposing the dielectric layer, removing the substrate and the adhesive layer to form an embedded layer with the exposed functional surfaces;
after forming the embedded layer, forming a wiring layer on the functional surfaces, wherein the wiring layer is electrically connecting to the electronic components;
forming a plurality of conductive connecting components within the dielectric layer, wherein the embedded layer has a bottom surface on an opposite side of the functional surface, and the conductive connecting components connect to the wiring layer, and an end of each of the conductive connecting components is exposed to the bottom surface of the embedded layer; and
after forming the conductive connecting components, laminating a cover layer over the dielectric layer and the wiring layer.

2. The method of claim 1, wherein the adhesive layer is an ultraviolet glue layer, and disposing the electronic components on the adhesive layer comprises:
irradiating ultraviolet radiation from a bottom surface of the substrate to solidify the ultraviolet glue layer and fix the electronic components, wherein the bottom surface is on an opposite side of the top surface of the substrate.

3. The method of claim 1, wherein forming the conductive connecting components comprises:
before disposing the dielectric layer, disposing a plurality of conductive pillar on the adhesive layer and between the electronic components.

4. The method of claim 1, wherein forming the conductive connecting components comprises:
before removing the substrate and the adhesive layer, forming a plurality of via holes within the dielectric layer, wherein the via holes penetrate the dielectric layer and the adhesive layer; and
filling a conductive material into the via holes.

5. The method of claim 1, further comprising:
before disposing the dielectric layer over the electronic components and the adhesive layer, disposing a baseplate on a bottom surface of the substrate, wherein the bottom surface is on an opposite side of the top surface of the substrate; and
removing the substrate and the adhesive layer comprises removing the baseplate.

6. The method of claim 1, wherein disposing the wiring layer comprises:
printing a conductive material on the embedded layer; and
solidifying the conductive material.

7. The method of claim 1, wherein the dielectric layer comprises a resin material, and the resin material is chosen from a group consisting of polyimide (PI), modified polyimide (MPI), perfluoroalkoxy resin (PFA) and liquid crystal polymer (LCP).

8. The method of claim 7, wherein the dielectric layer further comprises a plurality of hollow glass microspheres, and the hollow glass microspheres are mixed with the resin material.

9. A circuit board with embedded components, comprising:
a dielectric layer;
a plurality of electronic components embedded within the dielectric layer, wherein each of the electronic components has a functional surface and a plurality of pads exposed at the functional surfaces;
a wiring layer disposed on a top surface of the dielectric layer, wherein the wiring layer is electrically connecting to the electronic components;
a plurality of conductive connecting components penetrated the dielectric layer and disposed between the electronic components, wherein the conductive connecting components are electrically connected to the wiring layer, and an end of each of the conductive connecting components is exposed to a bottom surface of the dielectric layer; and
a cover layer disposed over the dielectric layer, the wiring layer and the conductive connecting components.

10. The circuit board with embedded components of claim 9, wherein the dielectric layer comprises a resin material, and the resin material is chosen from a group consisting of polyimide (PI), modified polyimide (MPI), perfluoroalkoxy resin (PFA) and liquid crystal polymer (LCP).

11. The circuit board with embedded components of claim 10, wherein the dielectric layer further comprises a plurality of hollow glass microspheres, and the hollow glass microspheres are mixed with the resin material.

12. The circuit board with embedded components of claim 11, wherein an average particle size of the hollow glass microspheres is 5 μm to 100 μm.
